(19) United States
(12) Patent Application Publication
(10) Pub. No.: US 2009/0052125 A1
(43) Pub. Date: Feb. 26, 2009

(54) METHOD OF FORMING A HOUSING HAVING A THIN WALL AND THE HOUSING

(75) Inventor: Hiroaki Hirao, Ome-shi (JP)

Correspondence Address: BLAKELY SOKOLOFF TAYLOR & ZAFMAN LLP, 1279 OAKMEAD PARKWAY, SUNNYVALE, CA, 94085-4040, US

(73) Assignee: KABUSHIKI KAISHA TOSHIBA, Tokyo (JP)

(21) Appl. No.: 12/265,650

(22) Filed: Nov. 5, 2008

Related U.S. Application Data
(62) Division of application No. 11/376,893, filed on Mar. 16, 2006, now Pat. No. 7,458,412.

(30) Foreign Application Priority Data
Apr. 15, 2005 (JP) 2005-118640

(51) Int. Cl. H05K 5/00

(52) U.S. Cl. 361/679.55; 361/679.01

(57) ABSTRACT

According to one embodiment, a housing is formed by using a pair of metal molds. The housing includes a first wall, second walls projecting from the first wall, and bosses projecting from the first wall. A molten material is filled into a molding space defined between the metal molds, and thereby a molded article having a shape corresponding to the housing is molded. The molded article has a plurality of first pin-receiving portions serving as the bosses, and a plurality of second pin-receiving portions projecting from the second walls. The first and the second pin-receiving portions are pushed by a plurality of ejector pins, and thereby the molded article is ejected from the metal molds.

### CROSS-REFERENCE TO RELATED APPLICATIONS

This application is a divisional application of U.S. patent application Ser. No. 11/376,893, filed Mar. 16, 2006, now U.S. Pat. No. ______, which is based upon and claims the benefit of priority from Japanese Patent Application No. 2005-118640, filed Apr. 15, 2005, the entire contents of which are incorporated herein by reference.

### BACKGROUND

1. Field

One embodiment of the invention relates to a method of forming a housing used for electronic apparatuses such as portable computers, in particular, a method of ejecting a molded article serving as a base of a housing from a metal mold by using a plurality of ejector pins. Further, the present invention relates to a housing that is molded by filling a molten material between a pair of metal molds.

2. Description of the Related Art

Recently, electronic apparatuses such as portable computers having a housing made of magnesium alloy are known. Housings made of magnesium alloy have advantages that reduction in weight and thickness can be more easily achieved while stiffness is secured than in housings made of synthetic resin or aluminum alloy.

Housings made of magnesium alloy are mass-produced by using molding devices. The molding device has a pair of metal molds which are detachably engaged. A molding space is formed between the metal molds. Molten magnesium alloy is filled into the molding space and hardened therein, and thereby a molded article having a shape corresponding to a housing is obtained. The molded article is ejected from the molds, and then subjected to chemical treatment, primer application, painting, and clear coating, etc.

When the molded article is ejected from the molds, a method of using a plurality of ejector pins is conventionally adopted. The ejector pins push up the molded article from one of the metal molds, and are vertically movably attached to one of the metal molds. The ejector pins are scattered to cover a wide range of the molded article such that they can push up the molded article without inclining the article.

On the other hand, a basic thickness of housings of magnesium alloy is empirically set to 0.8 mm or less. Therefore, the molded articles serving as a base of the housings are formed to have a very small thickness. Thus, if conventional ejector pins are adopted, the thin molded article may yield to a pushing force applied from the ejector pins when the molded article is ejected from the molds.

If the molded article is deformed, its surface serving as the exterior surface is warped. This warp causes diffusion of light after clear coating is applied to the molded article. Therefore, warp is particularly conspicuous in housings obtained by applying clear coating to molded articles. This causes deterioration in appearance of the housings.

### BRIEF DESCRIPTION OF THE SEVERAL VIEWS OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is a perspective view of an exemplary portable computer according to an embodiment of the present invention;

FIG. 2 is an exemplary perspective view of a cover of a first housing, in an inverted state, according to the embodiment of the present invention;

FIG. 3 is an exemplary enlarged perspective view of a circled area A in FIG. 2;

FIG. 4 is an exemplary enlarged perspective view of a circled area B in FIG. 2;

FIG. 5 is an exemplary enlarged perspective view of a circled area C in FIG. 2;

FIG. 6 is an exemplary enlarged perspective view of a circled area D in FIG. 2;

FIG. 7 is an exemplary enlarged perspective view of a circled area E in FIG. 2;

FIG. 8 is an exemplary enlarged perspective view of a circled area F in FIG. 2;

FIG. 9 is an exemplary enlarged perspective view of a circled area G in FIG. 2;

FIG. 10 is an exemplary enlarged perspective view of a circled area H in FIG. 2;

FIG. 11 is an exemplary enlarged perspective view of a circled area I in FIG. 2;

FIG. 12 is an exemplary enlarged perspective view of a circled area J in FIG. 2;

FIG. 13 is an exemplary enlarged perspective view of a circled area K in FIG. 2;

FIG. 14 is an exemplary enlarged perspective view of a circled area L in FIG. 2;

FIG. 15 is an exemplary enlarged perspective view of a circled area M in FIG. 2;

FIG. 16 is an exemplary enlarged perspective view of a circled area N in FIG. 2;

FIG. 17 is an exemplary enlarged perspective view of a circled area O in FIG. 2;

FIG. 18 is an exemplary plan view of a display cover being a part of a display unit according to the embodiment of the present invention;

FIG. 19 is an exemplary schematic cross sectional view of a molded article forming the cover according to the embodiment of the present invention;

FIG. 20 is an exemplary cross-sectional view illustrating a state where magnesium alloy is filled into a molding space between a pair of metal molds according to the embodiment of the present invention;

FIG. 21 is an exemplary cross-sectional view illustrating a state where the molded article is ejected from the metal molds by using ejector pins, according to the embodiment of the present invention; and

FIG. 22 is an exemplary perspective view of the molded article in a state where a second pin-receiving portion shown in FIG. 8 is ejected therefrom, according to the embodiment of the present invention.

### DETAILED DESCRIPTION

Various embodiments according to the invention will be described hereinafter with reference to the accompanying drawings. In general, according to one embodiment of the invention, a method of forming a housing having a first wall, a plurality of second walls projecting from the first wall, and a plurality of bosses projecting from the first wall at positions different from positions of the second walls, the method comprises preparing a pair of metal molds, filling a molten material into a molding space defined between the metal molds, and thereby molding a molded article having a shape corresponding to the housing, the molded article having a plurality of first pin-receiving portions serving as the bosses and a plurality of second pin-receiving portions projecting from the second walls, and ejecting the molded article from the metal molds by pushing the first pin-receiving portions and the second pin-receiving portions of the molded article by a plurality of ejector pins.

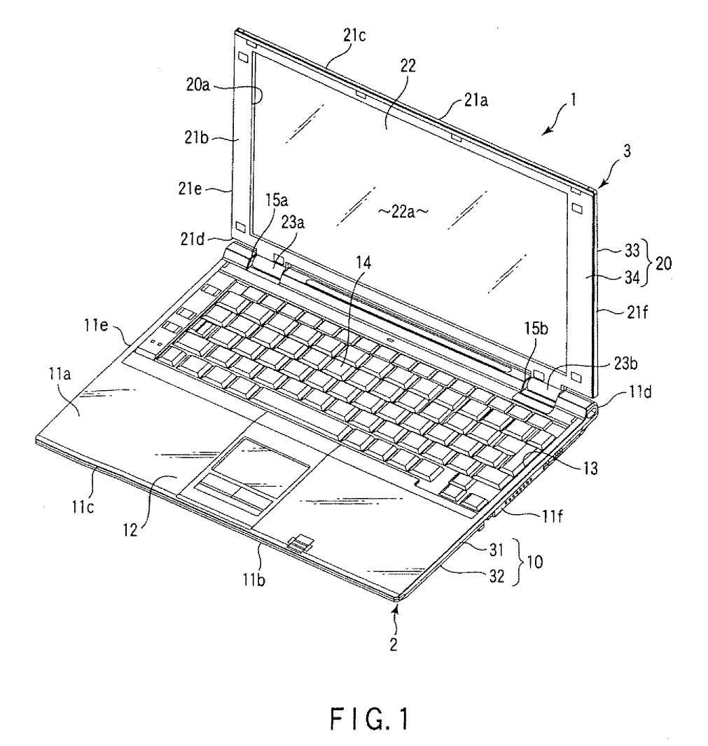

FIG. 1 illustrates a portable computer 1 being an example of an electronic apparatus. The portable computer 1 comprises a main unit 2 and a display unit 3. The main unit 2 has a first housing 10. The first housing 10 contains main components, such as a hard disk drive and a printed circuit board. The first housing 10 has a flat box shape having a top wall 11a, a bottom wall 11b, a front wall 11c, a rear wall 11d and left and right side walls 11e and 11f. The top wall 11a is an example of a first wall. A front half of an external surface of the top wall 11a serves as a palm rest 12. The front wall 11c, the rear wall 11d and the side walls 11e and 11f are an example of a third wall, and projects downward from edges of the top wall 11a.

The top wall 11a of the first housing 10 has a keyboard attaching portion 13. The keyboard attaching portion 13 is positioned in the rear of the palm rest 12, and supports a keyboard 14.

The first housing 10 has a pair of display support portions 15a and 15b at a rear end portion of the top wall 11a. The display support portions 15a and 15b are depressions each opened in the frontward, upward and rearward directions, and they are provided apart from each other in the width direction of the first housing 10.

The display unit 3 has a second housing 20 and a liquid crystal display panel 22. The second housing 20 has a rear wall 21a, a front wall 21h, and first to fourth peripheral walls 21c, 21d, 21e and 21f. The rear wall 21a is an example of an end wall. The front wall 21b has an opening portion 20a. The first to fourth peripheral walls 21c, 21d, 21e and 21f stand on edges of the rear wall 21a.

The liquid crystal display panel 22 is contained in the second housing 20. The liquid crystal display panel 22 has a screen 22a that displays images. The screen 22a is exposed to the outside of the second housing 20 through the opening portion 20a of the front wall 21b.

The second housing 20 has a pair of leg portions 23a and 23b projecting from its bottom end. The leg portions 23a and 23b are apart from each other in the width direction of the second housing 20. The leg portions 23a and 23b are guided into the display support portions 15a and 15b of the first housing 10, respectively. Each of the leg portions 23a and 23b is supported by the first housing 10 with a hinge (not shown). Therefore, the display unit 3 is rotatable between a closed position and an open position. In the closed position, the display unit 3 is laid on the main unit 2 to cover the palm rest 12 and the keyboard 14 from above. In the open position, the display unit 3 stands on the rear end portion of the main unit 2 to expose the palm rest 12 and the keyboard 14.

The first housing 10 comprises a cover 31 and a case 32. The cover 31 and the case 32 are formed of, for example, magnesium alloy mainly consisting of magnesium. The cover 31 forms the top wall 11a, the front wall 11c, the rear wall 11d and the left and right side walls 11e and 11f of the first housing 10. The case 32 forms the bottom wall 11b of the first housing 10.

The cover 31 serves as a main part of the first housing 10. The cover 31 is exposed to the outside of the portable computer 1 when the display unit 3 is rotated to the open position, and very conspicuous in terms of the appearance. The cover 31 is set to have a thickness of 0.8 mm or less, preferably 0.6 mm or less.

The second housing 20 comprises a display cover 33 and a display mask 34. The display cover 33 and the display mask 34 are formed of, for example, magnesium alloy mainly consisting of magnesium. The display cover 33 forms the rear wall 21a, the first to fourth peripheral walls 21c, 21d, 21e, and 21f of the second housing 20. The display mask 34 forms the front wall 21b of the second housing 20.

The display cover 33 serves as a main part of the second housing 20. The display cover 33 is always exposed to the outside of the portable computer 1 regardless of the position of the display unit 3, and very conspicuous in terms of the appearance. At least a portion of the display cover 31 opposed to the liquid crystal display panel 22 is set to have a thickness of 0.8 mm or less, preferably 0.6 mm or less.

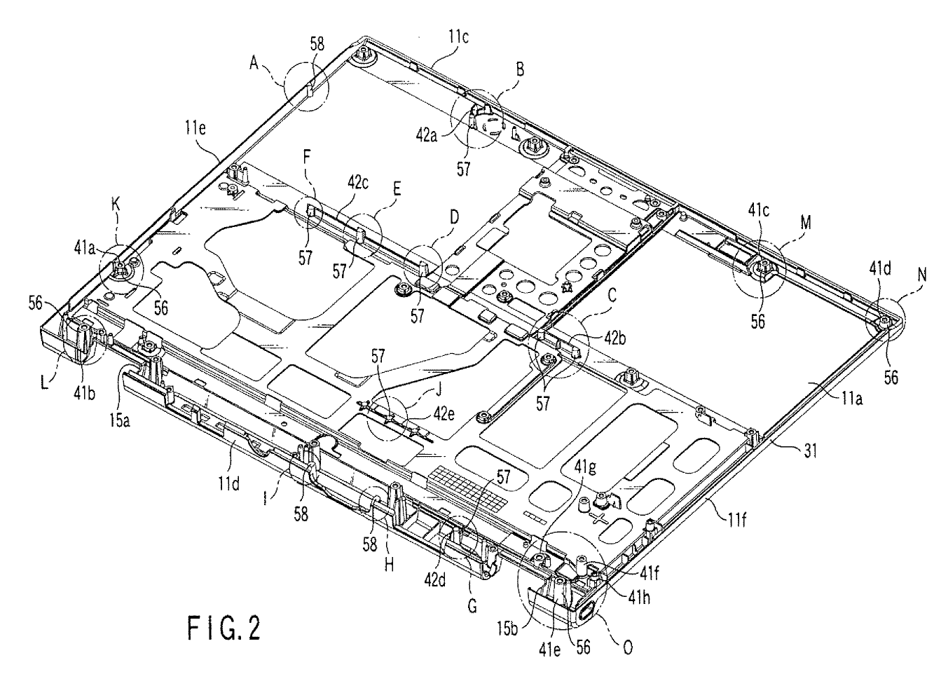

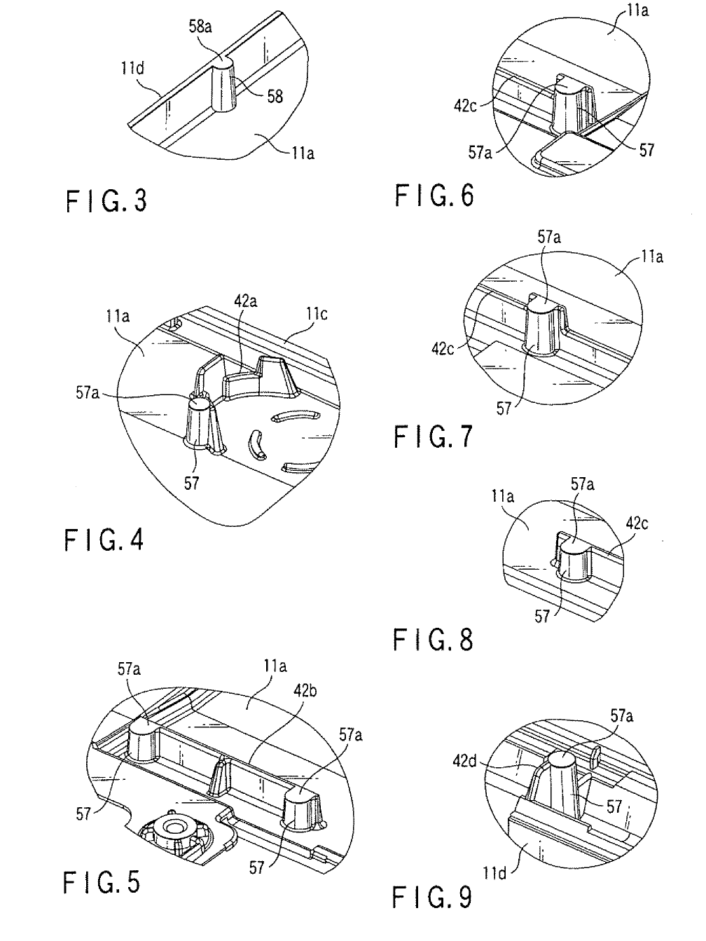

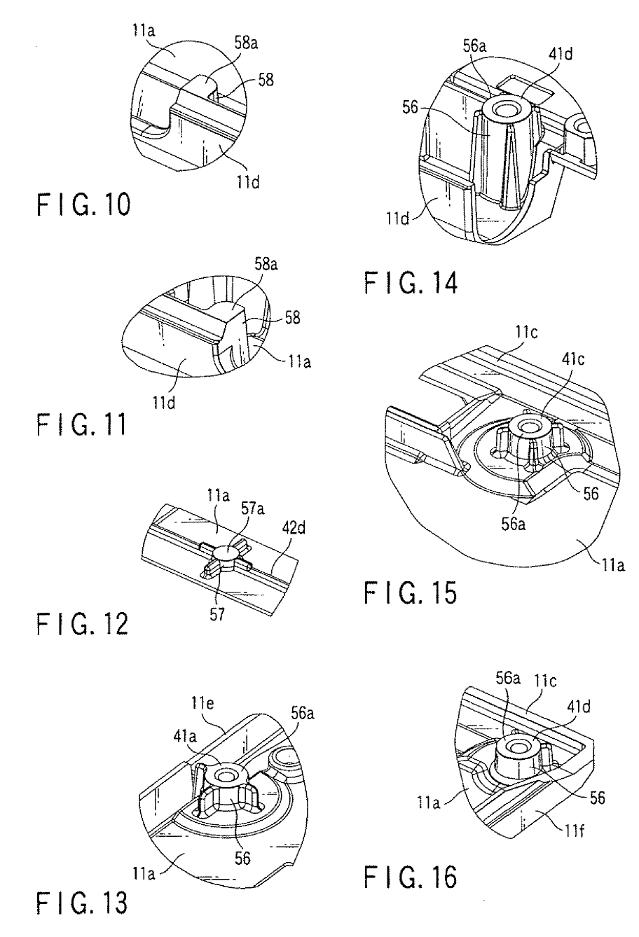

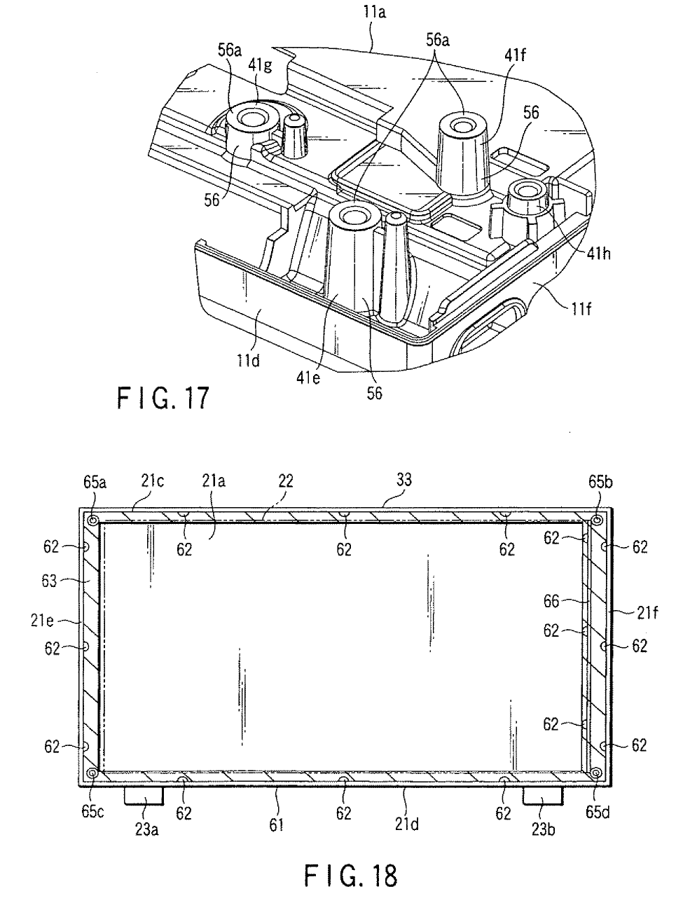

FIG. 2 illustrates the cover 31 in an inverted state. As shown in FIGS. 2 to 17, a plurality of bosses 41a to 41h and a plurality of rib-shaped partition walls 42a to 42e are formed as unitary piece with the cover 31, on an internal surface of a portion of the cover 31 forming the top wall 11a of the first housing 10. The bosses 41a to 41h project from the internal surface of the top wall 11a in the thickness direction of the top wall 11a. The partition walls 42a to 42e are an example of a second wall, and project from the internal surface of the top wall 11a in the thickness direction of the top wall 11a. The bosses 41a to 41h are provided in positions different from those of the partition walls 42a to 42e.

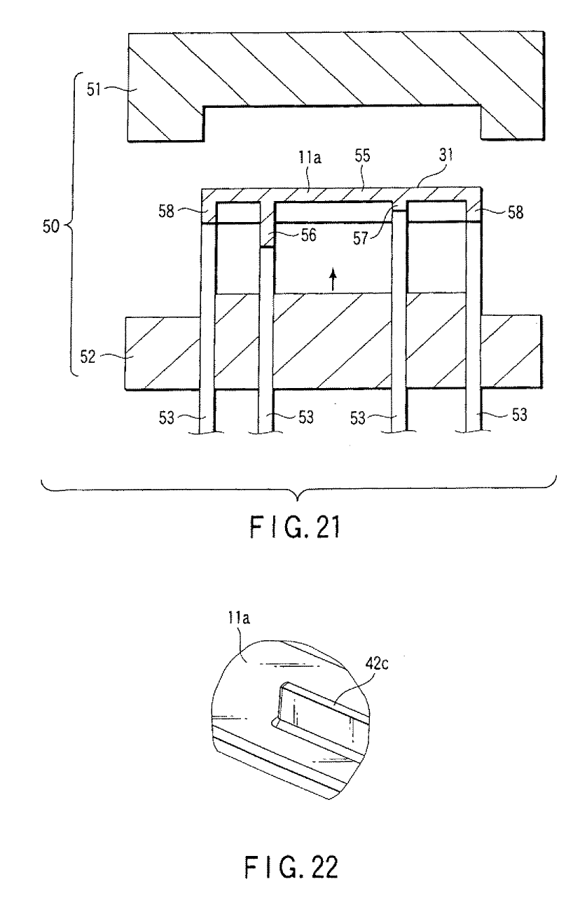

Each of the first housing 10 and the second housing 20 is molded by using a molding device. FIGS. 20 and 21 illustrate a molding device 50 for molding the cover 31 of the first housing 10. The molding device 50 comprises a first metal mold 51 having a cavity, a second metal mold 52, and a plurality of ejector pins 53.

The first metal mold 51 and the second metal mold 52 are engaged in a vertically separatable manner. The first metal mold 51 and the second metal mold 52 forms a molding space 54 when they are engaged.

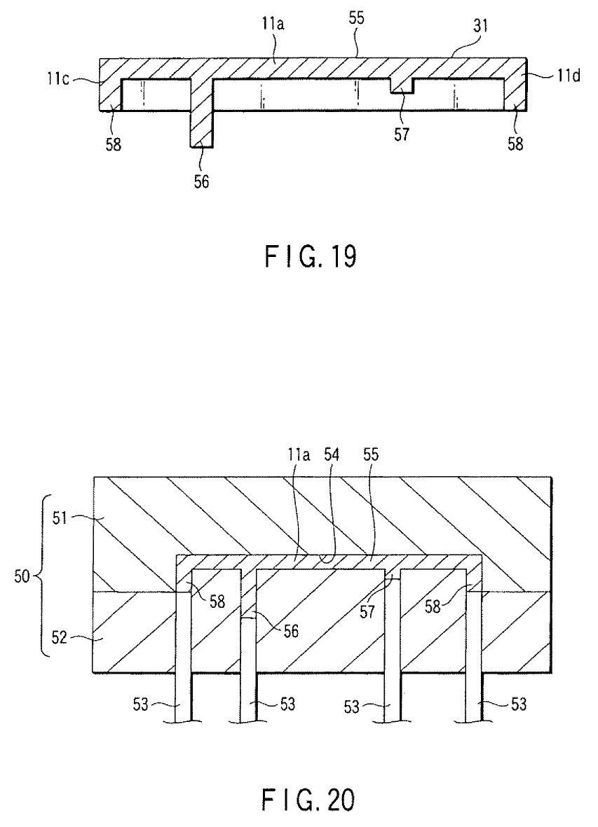

The molding space 54 is used for obtaining a molded article 55 having a shape corresponding to the cover 31. As schematically shown in FIGS. 19 and 20, the molded article 55 has a plurality of first pin receiving portions 56 serving as the boss portions 41a to 41h, a plurality of second pin-receiving portions 57 protecting from portions serving as the partition walls 42a to 42e, and a plurality of third pin-receiving portions 58 projecting from portions serving as the front wall 11c, the side wall 11e and the rear wall 11d. In other words, the first and the second metal molds 51 and 52 are designed such that the first to third pin-receiving portions 56 to 58 are formed together with the molded article 55.

As shown in FIGS. 2 to 17, the first to third pin-receiving portions 56 to 58 are an example of projections, and each pin-receiving portion has a generally columnar shape. The first to third pin receiving portions 56 to 58 project from an internal surface of a portion, which serves as the top wall 11a, in the molded article 55. The first to third pin receiving portions 56 to 58 have respective tip end surfaces 56a to 58a. The tip end surface 57a of each second pin-receiving portion 57 preferably has a thickness greater than the thickness of portions of the molded article 55 serving as the partition walls 42a to 42e, and is smaller than the tip end surface 56a of each first pin-receiving portion 56. Further, the first to third pin-receiving portions 56 to 58 are provided to scatter over a wide range of the portion, which serves as the top wall 11a, in the molded article 55.

The ejector pins 53 push up and eject the molded article 55 from the second metal mold 52, and are vertically movably supported by the second metal mold 52. The ejector pins 53 are provided in positions corresponding to the first to third pin-receiving portions 56 to 58 of the molded article 55, such that they can push up the molded article 55 without inclining it.

Next, explained is a procedure of molding the cover 31 of the first housing 10 using the molding device 50.

First, the first metal mold 51 and the second metal mold 52 are engaged with each other, and thereby the molding space 54 is formed between the first and second metal molds 51 and 52. Next, molten magnesium alloy is injected into the molding space 54. When the molding space 54 has been filled with the magnesium alloy, after a cooling period of several seconds, the first metal mold 51 and the second metal mold 52 are moved in directions of going away from each other. This step exposes a molded article 55 having a shape corresponding to the cover 31 to the outside of the molding device 50, and thus the molded article 55 is ejected from the molding device 50.

As shown in FIG. 21, when the molded article 55 is ejected from the molding device 50, the ejector pins 53 are ascended. The ejector pins 53 meet the tip end surfaces 56a to 58a of the first to third pin-receiving portions 56 to 58 of the molded article 55, and push up the molded article 55 from the second metal mold 52. As a result, the molded article 55 is separated from the second metal mold 52, and thereby the molded article 55 is ejected from the molding device 50.

After the molded article 55 is ejected from the molding device 50, the bosses 41a to 41h are formed by processing the first pin-receiving portions 56. Among the second pin-receiving portions 57, those which do not obstruct accommodation of main components in the first housing 10 may be maintained in the molded article 55. Some of the second pin-receiving portions 57 which interfere with the main components are cut away from the molded article 55. Thereby, as is clear from comparison between FIG. 8 and FIG. 22, some of the second pin-receiving portions 57 are removed from the partition wall 42c. Some of the third pin-receiving portions 58 are removed from the molded article 55, if necessary.

After completion of processing of the molded article 55, the molded article 55 is subjected to chemical treatment for rust proofing. Then, the molded article 55 is subjected to primer application, painting, and clear coating being an example of high-gloss coating. The gloss-coating is applied to enhance abrasion resistance and appearance quality of the molded article 55, and is not limited to coating using transparent paint.

Through the above steps, the cover 31 being part of the first housing 10 is finished.

According to the above method of forming the cover 31, when the molded article 55 serving as a base of the cover 31 is ejected from the molding device 50, the ejector pins 53 pushes upward the first to third pin-receiving portions 56 to 58 of the molded article 55. Each of the first to third pin-receiving portions 56 to 58 has a thickness larger than that of portions of the molded article 55 serving as the thin top wall 11a, and has high stiffness. This means that the ejector pins 53 push up the portions having high stiffness in the molded article 55.

In other words, the ejector pins 53 do not push up the portions of the molded article 55, which are thin and easily deformed, and the molded article 55 does not yield to the pushing force applied from the ejector pins 53. Therefore, the molded article 55 is finished as cover 31 having little warp or deformation, and it is possible to obtain a cover 31 having good appearance and not causing light diffusion.

The case 32 of the first housing 10 can be formed by using a molding device similar to that of the cover 31. Therefore, explanation of the method of forming the case 32 is omitted.

Next, explained is a method of forming the display cover 33 of the second housing 20. A portion of the display cover 33, serving as the rear wall 21a, has a size to cover the liquid crystal display panel 22, and a very small thickness of 0.6 mm.

A molding device for molding the display cover 33 comprises a first metal mold 51, a second metal mold 52 and a plurality of ejector pins 53, in the same manner as the molding device 50 for forming the cover 31. A molding space 54 defined between the first metal mold 51 and the second metal mold 52 is used for obtaining a molded article 61 having a shape corresponding to the display cover 33 as shown in FIG. 18.

The molded article 61 has a plurality of pin-receiving portions 62 projecting from portions serving as the first to fourth peripheral walls 21c to 21f. Each of the pin-receiving portions 62 has a generally columnar shape, and is provided on a peripheral area 63 in the portion of the molded article 61 serving as the rear wall 21a. As shown in FIG. 18 with hatching, the peripheral area 63 extends along the first to fourth peripheral walls 21c to 21f of the molded article 61, and surrounds the liquid crystal display panel 22.

Further, if the molded article 61 also has a plurality of bosses 65a to 65d projecting from the portion serving as the rear wall 21a and a standing wall 66 projecting from the portion serving as the rear wall 21a, the bosses 65a to 65d and the standing wall 66 are provided in the peripheral area 63. The standing wall 66 supports the liquid crystal display panel 22, and has some of the pin-receiving portions 62. Therefore, the first and second metal molds 51 and 52 are designed such that the pin-receiving portions 62, the bosses 65a to 65d and the standing wall 66 are formed together with the molded article 61.

The ejector pins 53 push up and eject the molded article 61 from the second metal mold 52, and are vertically movably supported by the second metal mold 52. The ejector pins 53 are provided in positions corresponding to the pin-receiving portions 62 and the boss portions 65a to 65d of the molded article 61, such that they can push up the molded article 61 without inclining it.

To form the display cover 33, first, molten magnesium alloy is injected into the molding space 54 of the molding device 50. Then, after a cooling period of several seconds, the first metal mold 51 and the second metal mold 52 are moved in directions of going away from each other, and thereafter the molded article 61 is ejected therefrom.

When the molded article 61 is ejected from the molding device 50, the ejector pins 53 are ascended. The ejector pins 53 meet the pin-receiving portions 62 and the bosses 65a to 65d of the molded article 61, and push up the molded article 61 from the second metal mold 52. As a result, the molded article 61 is separated from the second metal mold 52, and thereby the molded article 61 is ejected from the molding device 50.

After the molded article 55 is ejected from the molding device 50, the bosses 65a to 65d are processed and, if necessary, some of the second pin-receiving portions 62 are cut away from the molded article 61, in the same manner as in the cover 31. Then, the molded article 61 is subjected to chemical treatment for rust proofing, primer application, painting, and gloss coating. Through the above steps, the display cover 33 being part of the second housing 20 is finished.

According to the above method of forming the display cover 33, when the molded article 61 serving as a base of the display cover 33 is ejected from the molding device 50, the ejector pins 53 pushes upward the pin-receiving portions 62 and the bosses 65a to 65d of the molded article 61. Therefore, the ejector pins 53 do not push up a thin portion of the molded article 61, which corresponds to the rear wall 21a, and the molded article 61 does not yield to the pushing force applied from the ejector pins 53. Therefore, the molded article 61 is finished as display cover 33 having little warp or deformation and having high quality.

Therefore, it is possible to obtain a display cover 33 having good appearance even if the molded article 61 is subjected to gloss coating.

The display mask 34 of the second housing 20 is formed by using a molding device similar to that for the display cover 33. Therefore, explanation of a method of forming the display mask 34 is omitted.

The present invention is not limited to a housing for portable computers and a method of forming thereof. For example, the present invention can be carried out as a housing for electronic apparatuses other than portable computers or other apparatuses.

While certain embodiments of the inventions have been described, these embodiments have been presented by way of example only, and are not intended to limit the scope of the inventions. Indeed, the novel methods described herein may be embodied in a variety of other forms; furthermore, various omissions, substitutions and changes in the form of the methods described herein may be made without departing from the spirit of the inventions. The accompanying claims and their equivalents are Intended to cover such forms or modifications as would fall within the scope and spirit of the inventions.

What is claimed is:

1. A housing formed by filling a molten material between at least two metal molds, the housing comprising:
a first wall having an exterior surface and an internal surface;
a plurality of second walls extending from the first wall;
a partition wall projecting from the internal surface of the first wall, the partition wall being surrounded by the plurality of second walls and is formed as unitary piece of the housing; and
a first plurality of pin-receiving portions which is formed as a part of the partition wall, the first plurality of pin-receiving portions being pushed by a first plurality of ejector pins when the housing is ejected from the metal molds.

2. The housing of claim 1, wherein the partition wall is configured to be oriented lengthwise and in parallel with at least one of the plurality of second walls.

3. The housing of claim 1, further comprising a plurality of bosses projecting from the internal surface of the first wall at positions different from position of the partition wall, the plurality of bosses being pushed by a second plurality of ejector pins when the housing is ejected from the metal molds.

4. The housing of claim 3, wherein the plurality of bosses being formed in positions adjacent to and in contact with the plurality of second walls.

5. The housing of claim 4, wherein the first plurality of pin-receiving portions and the plurality of bosses are scattered over a wide range of the first wall.

6. The housing of claim 1, wherein each of the first plurality of pin-receiving portions having a tip end surface that makes contact with a corresponding one of the first plurality of ejector pins, each of the tip end surfaces for the first plurality of pin-receiving portions has a size greater than a thickness of the partition wall.

7. The housing of claim 6, wherein the first plurality of pin-receiving portions projects outwardly, thereby increasing a width of the partition wall.

8. The housing of claim 1, further comprising a second plurality of pin-receiving portions formed as part of the plurality of second walls, the second plurality of pin-receiving portions pushed by a second plurality of ejector pins when the housing is ejected from the metal molds.

9. A housing formed by filling a molten material between at least two metal molds, the housing comprising:
a top wall having an internal surface;
a plurality of peripheral walls extending from the top wall; and
at least one pin-receiving portion formed as a part of a partition wall that is surrounded by the plurality of peripheral walls and projects from the internal surface of the top wall, the at least one pin-receiving portions being pushed by one or more corresponding ejector pins when the housing is ejected from the metal molds.

10. The housing of claim 9, wherein the partition wall is formed as a unitary piece of the housing

11. The housing of claim 9, wherein the at least one pin-receiving portion further comprises a plurality of pin-receiving portions formed as part of a first peripheral wall of the plurality of peripheral walls and projecting laterally thereby increasing a width of the first peripheral wall at the plurality of pin-receiving portions, the plurality of pin-receiving portions being pushed by the ejector pins when the housing is ejected from the metal molds.

12. The housing of claim 9, further comprising a plurality of bosses projecting from the internal surface of the top wall at positions different from position of the partition wall, the plurality of bosses pushed by a plurality of ejector pins when the housing is ejected from the metal molds.

13. The housing of claim 12, wherein the plurality of bosses being formed In positions adjacent to and in contact with the plurality of peripheral walls.

14. The housing of claim 13, wherein the plurality of pin-receiving portions and the plurality of bosses are scattered over a wide range of the top wall.

15. The housing of claim 9, wherein the top wall having an exterior surface being a palm rest for a portable computer.

16. A housing formed by filling a molten material between a pair of metal molds, the housing comprising:
an end wall covering a component;
a plurality of peripheral walls extending from the end wall and surrounding the component;
a standing wall surrounded by the peripheral walls, the standing wall being formed as an unitary piece of the housing and projecting from an internal surface of the end wall; and
a first plurality of pin-receiving portions which is formed as a part of the standing wall, wherein the first plurality of pin-receiving portions in contact with a first plurality of ejector pins when the housing is ejected from the metal molds.

17. The housing of claim 16, wherein the first plurality of pin-receiving portions projecting laterally thereby increasing a width of the standing wall.

18. The housing of claim 16, further comprising a second plurality of pin-receiving portions formed as part of the plurality of peripheral walls, the second plurality of pin-receiving portions in contact with a second plurality of ejector pins when the housing is ejected from the metal molds.

19. The housing of claim 18, further comprising a plurality of bosses formed in positions adjacent to the plurality of the peripheral walls.

20. The housing of claim 16, wherein the standing wall being configured to be oriented lengthwise and in parallel with at least one of the plurality of the peripheral walls and the standing wall being situated between the component and at least one of the plurality of the peripheral walls.
